(19) United States
(12) Patent Application Publication
(10) Pub. No.: US 2020/0144757 A1
(43) Pub. Date: May 7, 2020

(54) RESILIENT SNAP CONNECTOR SYSTEM

(71) Applicants: JOSEPH RIORDAN, Black Diamond, WA (US); Brian Riordan, Kent, WA (US)

(72) Inventors: JOSEPH RIORDAN, Black Diamond, WA (US); Brian Riordan, Kent, WA (US)

(21) Appl. No.: 16/733,562

(22) Filed: Jan. 3, 2020

Related U.S. Application Data
(63) Continuation-in-part of application No. 15/586,230, filed on May 3, 2017.
(60) Provisional application No. 62/331,417, filed on May 3, 2016.

(51) Int. Cl. H01R 13/506; H05K 5/00; A47G 25/06; H01R 12/77; F16B 21/08

(52) U.S. Cl. CPC H01R 13/506; H05K 5/0013; H01R 2201/12; H01R 12/77; F16B 21/088; A47G 25/0678

(57) ABSTRACT

The resilient snap connector system includes a resilient connector strap selectively coupled to a first connector and a second connector spaced from the first connector to form a bridged connection between the first and second connectors. In a typical use, the first connector is fixed to a deformable object, such as a tarp, and the second connector is fixed to another object, such as a hull. The resilient connector strap enables connection between the objects when the separation distance may be too long for normal engagement of the connectors by stretching to accommodate the separation. A pull tab is provided on the resilient connector strap to assist in the stretching and coupling.

### CROSS-REFERENCE TO RELATED APPLICATION

This application is a continuation-in-part of Ser. No. 15/586,230, filed May 3, 2018, which application claims the benefit of U.S. Provisional Patent Application Ser. No. 62/331,417, filed May 3, 2016.

### BACKGROUND OF THE INVENTION

### 1. Field of the Invention

The present invention relates to fasteners, and particularly to a resilient snap connector system for ease of connecting separated objects with minimal effort.

### 2. Description of the Related Art

Press-fit or snap-fit fasteners, in general, are commonly used fasteners for many different applications. In the boating industry, the snap-fit fastener is often applied to secure a fabric canvas or tarp to the hull of the boat for weather protection and the like. These tarps, unfortunately, tend to shrink over time from environmental exposure and other factors, which renders the process of connecting the male and female portions of the fasteners a more difficult and physically demanding task each time, especially when the task must be performed frequently. Once connected, the shrunken tarp also presents other difficulties, such as adding excessive tension to the fasteners, or even potential tearing of the tarp in extreme cases. Excessive tension can also cause the fasteners to prematurely disconnect and/or pull the fastener components from the hull with resulting damage to the hull. Thus, a resilient snap connector system solving the aforementioned problems is desired.

### SUMMARY OF THE INVENTION

The resilient snap connector system includes a resilient connector strap selectively coupled to a first connector and a second connector spaced from the first connector to form a bridged connection between the first and second connectors. In a typical use, the first connector is fixed to a flexible object, such as a tarp, and the second connector is fixed to another object, such as a hull. The resilient connector strap enables connection between the objects when the separation distance may be too long for normal engagement of the connectors by stretching to accommodate the separation. A pull tab is provided on the resilient connector strap to facilitate stretching and coupling the connectors together.

These and other features of the present invention will become readily apparent upon further review of the following specification and drawings.

### BRIEF DESCRIPTION OF THE DRAWINGS

FIG. 1 is an environmental, perspective view of a resilient snap connector system according to the present invention.

FIG. 2A is an environmental side view in section of a first connector of the resilient snap connector system of FIG. 1.

FIG. 2B is an environmental side view in section of a second connector of the resilient snap connector system of FIG. 1.

FIG. 3 is an environmental perspective view of an alternative embodiment of a resilient snap connector system according to the present invention.

FIG. 4 is a perspective view of a resilient connector strap of the resilient snap connector system of FIG. 3.

FIG. 5A is an exploded environmental perspective view of the resilient snap connector system of FIG. 3.

FIG. 5B is an environmental perspective view of the resilient snap connector system of FIG. 3, shown before fastening the connectors.

FIG. 6 is a perspective view of an alternative embodiment of a resilient connector strap for a resilient snap connector system according to the present invention.

FIG. 7 is a perspective view of an alternative embodiment of an anchor connector for a resilient snap connector system according to the present invention.

FIG. 8 is a perspective view of a further alternative embodiment of an anchor connector for a resilient snap connector system according to the present invention.

FIG. 9 is a perspective view of an alternative embodiment of a resilient connector strap for a resilient snap connector system according to the present invention.

FIG. 10 is a perspective view of an alternative embodiment of a resilient connector strap for a resilient snap connector system according to the present invention.

FIGS. 11A-11C are environmental, perspective views of the resilient snap connector system according to FIG. 10 in three stages of attachment to a grommet located in a tarp.

Similar reference characters denote corresponding features consistently throughout the attached drawings.

### DETAILED DESCRIPTION OF THE PREFERRED EMBODIMENTS

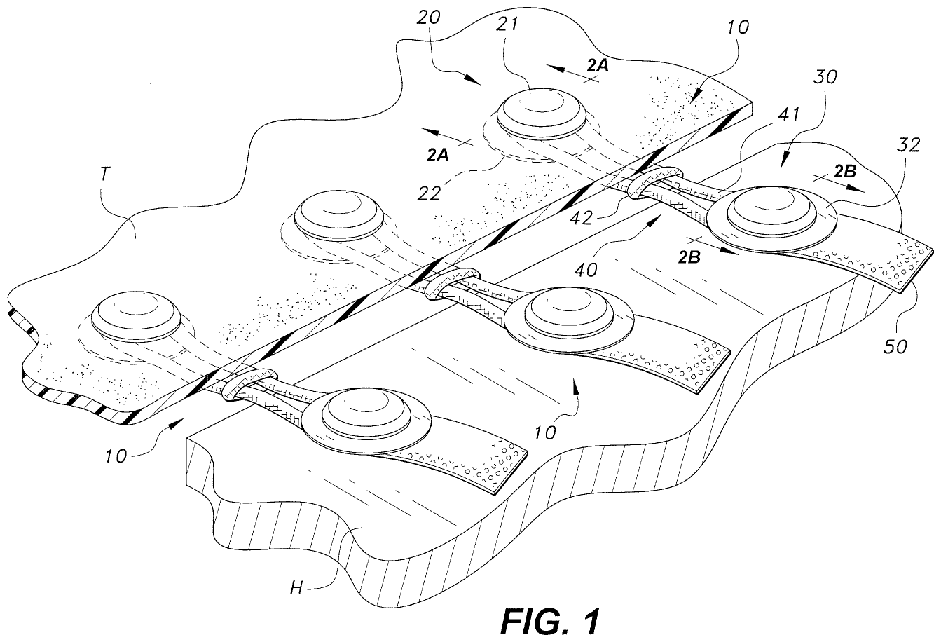

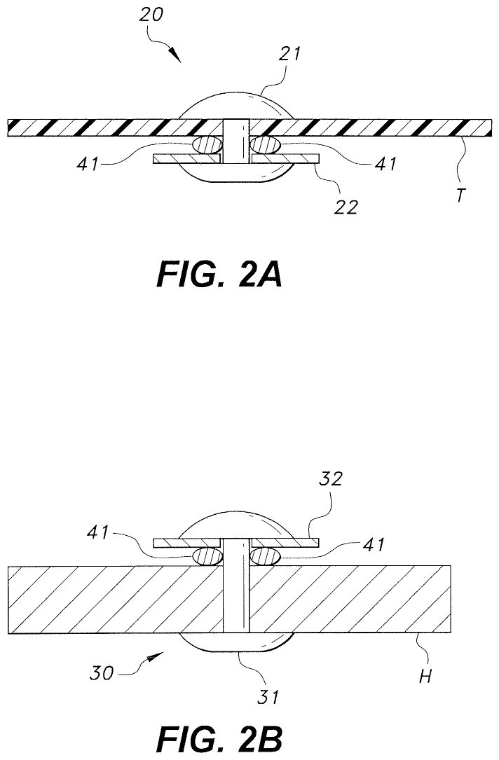

The resilient snap connector system, a first embodiment of which is generally referred to by the reference number 10 (shown in FIGS. 1 through 2B), provides a means of securely connecting separated components or elements with relative ease. The resilient snap connector system 10 may be used in conjunction with existing snap-fit fastener hardware with minimal modifications, or as a replacement therefor. As best seen in FIGS. 1, 2A, and 2B, the resilient snap connector system 10 includes a first connector 20 configured to be fixed to an element or component to be positioned for subsequent connection, a second connector 30 configured to be fixed to a stationary object or anchor point, an elongate resilient connector strap 40 with one end coupled to the first connector 20 and the other end coupled to the second connector 30, and an elongate pull tab 50 coupled to the other end of the resilient connector strap 40.

As best seen in FIG. 2A, the first connector 20 is preferably a female snap-fit component or member 21 fixed to an object, such as near an edge of exemplary tarp T. A fender washer 22 is slidably mounted to the post of the female snap-fit member 21 to define a gap in a general shape of an annular groove between the head of the female snap-fit member 21 and a surface of the object for securing one end of the resilient connector strap 40. The fender washer 22 serves as a flange with suitable surface area for capturing and preventing the end of the resilient connector strap 40 from dislodging once secured. The head of the first connector 20 may be provided with a cap, preferably dome-shaped, to cover the end of the post.

As best seen in FIG. 2B, the second connector 30 is preferably a male snap-fit component or member 31 fixed to another object, such as a hull of a marine vehicle. The second connector 30 serves as an anchor for the resilient snap connector system 10. As such, the second connector 30 is also referred to as an anchor connector herein. A fender washer 32 is slidably mounted to the post of the male snap-fit member 31 to define an annular groove between the head of the male snap-fit member 31 and a surface of the object for securing the other end of the resilient connector strap 40. The fender washer 32 serves as a flange with suitable surface area for capturing and preventing the other end of the resilient connector strap 40 from dislodging once secured. The head of the second connector 30 may also be provided with a cap, preferably dome-shaped, to cover the end of the post.

The resilient connector strap 40 is preferably an elongate strip of elastic cord 41 formed into an endless loop. A choke tie 42 is secured near the middle of the loop to form a pair of intermediate loops in a figure eight configuration. In use, one loop, i.e., one end of the resilient connector strap 40, hooks over the post of the female snap-fit member 21 to be trapped between the fender washer 22 and the surface of the object to which the female snap-fit member 21 is attached with the choke tie 42 assisting in retaining the connection to the female snap-fit member 21, while the other loop, i.e. the other end of the resilient connector strap 40, hooks over the post of the male snap-fit member 31 to be trapped between the fender washer 32 and the surface of the object to which the male snap-fit member 31 is attached. In the case of securing a tarp onto the hull of a boat, the intermediate loop for the first connector 20 hooks underneath the tarp T, and the intermediate loop for the second connector 30 hooks between the hull H and the fender washer 32. Moreover, the resilient connector strap 40 forms a bridge that spans the gap between an edge of the tarp T and the anchor point on the hull H, the gap existing due to tarp shrinkage. When connected thusly, the resiliency and elasticity of the elastic cord 41 relieves much of the tension that may exist from a stretched tarp. The elastic cord 41 is preferably weather-resistant to withstand the rigors of the environment. It is also contemplated that the choke tie 42 can be slidable along the resilient connector strap 40 to adjust for different size connectors and/or separation between connectors in performing the retention function.

To ease installation of the resilient connector strap 40, a pull tab 50 is attached to one of the intermediate loops in the resilient connector strap 40. The pull tab 50 is preferably an elongate strip of material dimensioned and configured for easy grasping by a user's hand. In use, the user pulls on the pull tab 50 with one of the intermediate loops of the elastic cord 41 hooked to the first connector 20. The pulling action stretches the elastic cord 41 until the user maneuvers the other intermediate loop to hook over the second connector 30 beneath the fender washer 32. Thus, it can be seen that the resilient snap connector system 10 enables the user to easily connect the tarp T to the hull H with minimal physical effort, despite the inherent difficulties in stretching a shrunken tarp with conventional snap-fit fasteners.

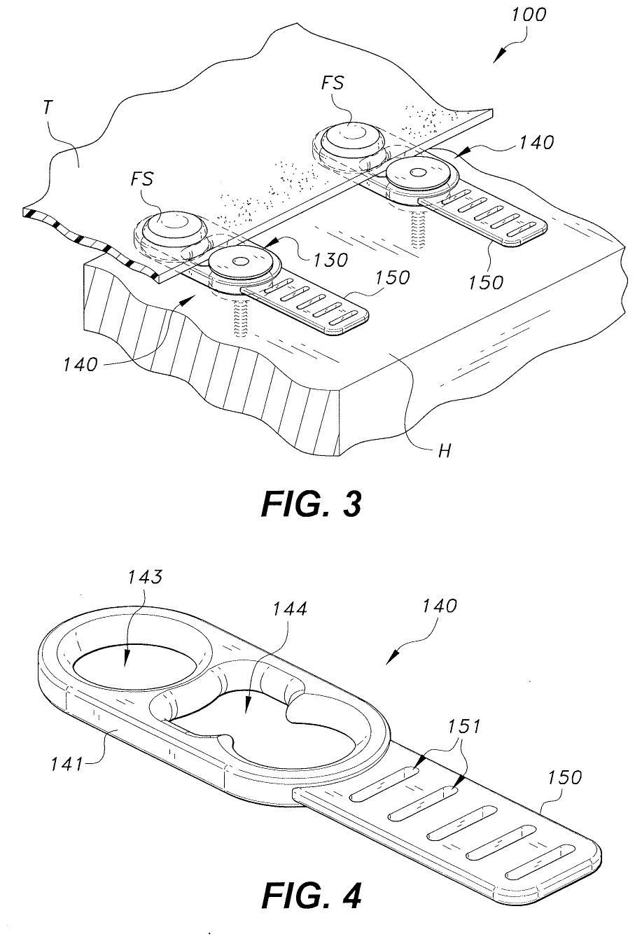

Another embodiment of a resilient snap connector system is shown in FIGS. 3, 4, 5A, and 5B. In this embodiment, the resilient snap connector system 100 may be applied in at least two different configurations, the first as a retrofit configuration, and the second as a replacement for the typical snap-fit fasteners found on hulls H and tarps T, for example.

As shown in FIGS. 3, 4, and 5A, the resilient snap connector system 100 includes a first connector 120 fixed to an object, such as the tarp T. A second connector 130 is fixed to another object, such as the hull H, and serves as an anchor point thereon. An elongate, resilient connector strap 140 interconnects the first connector 120 to the second connector 130 to selectively secure the tarp T to the hull H.

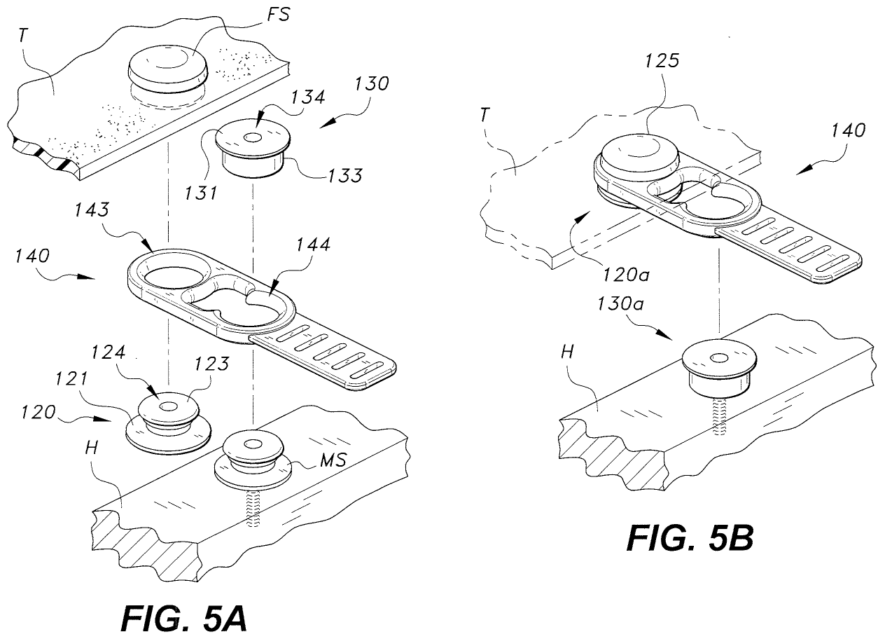

FIG. 5A depicts the resilient snap connector system 100 employed in a retrofit configuration. As shown, the first connector 120 is a generally cylindrical member having a broad head 121 and an elongate, generally flared or parabolic post 123 extending from the head 121. The parabolic post 123 may be provided with a throughbore 124 for selective mounting or fixing of this member or other elements thereon. The parabolic post 123 has the general shape of a male component of a snap-fit fastener to enable selective connection with the female snap-fit fastener component FS on the tarp T. The parabolic shape also forms an annular groove on the post 123.

The second connector has a relatively broad head 131 and a cylindrical post 133 extending from the head 131. The cylindrical post 133 is preferably hollow, and a throughbore 134 extends into the cylindrical post 133 from the head 131. As with the throughbore 124, the throughbore 134 permits selective mounting or fixing of the second connector 130 or other elements thereon The cylindrical post 133 has the general shape of a female component of a snap-fit fastener to enable selective connection with a male snap-fit fastener component MS. When mounted thus, the post 133 forms an annular groove between the head 131 and the male snap-fit fastener component MS and/or the surface of the hull H. The annular grooves on each post serves as mounting members for connecting the resilient connector strap 140. The mounting of the first connector 120 and the second connector 130 to their respective objects can be by any conventional means, such as riveting and screw fasteners.

As best seen in FIG. 4, the resilient connector strap 140 includes a generally oblong-shaped connection portion 141 and a pull tab 150 extending from one end of the connection portion 141. The pull tab 150 is preferably integral with the connection portion 141 and constructed from the same resilient material. The material is preferably a weather-resistant elastic plastic, such as synthetic rubber and the like.

The connection portion 141 includes a first ring 143 configured to selectively wrap around the post of the first connector 120. The first ring 143 is generally circular to conform to the contours of the post. The inner wall of the first ring 143 is preferably beveled, curved or rounded to enable secure engagement with the post.

A second ring 144, adjacent the first ring 143, is also formed in the connection portion 141. The second ring 144 is configured to wrap around the post of the second connector 130. However, the second ring 144 has a generally rectangular or oblong cutout merged with the second ring 144 at its circumference by a narrow neck, the cutout having a width slightly greater than the diameter of the ring 144, the ring 144 having a diameter slightly greater than the diameter of the post 133 of the second connector 130. The greater width of the cutout allows the head 131 of the second connector 130 to be inserted through the cutout, and the elastic tension on the connector portion 141 causes the post 133 of the second connector 130 to slide past the neck into the ring 144, where it is secured by the greater diameter of the head 131 of the second connector 130. The inner wall of the second ring 144 may be beveled or rounded to conform with the contours of the post 133.

The pull tab 150 is preferably an elongate, generally rectangular strip of material extending from the one end of the connection portion 141. The pull tab 150 may be provided with one or more cutouts or slots 151 as a means of enhancing grip, as well as enhancing elasticity.

In use in a retrofit configuration, the user fixes the first connector 120 to the female snap-fit fastener component FS that usually extends underneath the tarp T. The second connector 130 is also fixed to the male snap-fit fastener component MS that usually extends from the surface of the hull H. Then the user wraps the first ring 143 around the post 123 of the first connector 120. Using the first connector 120 as a temporary anchor, the user pulls the pull tab 150, stretching the connection portion 141 until a majority of the second ring 144 can be pulled over the post 133 of the second connector 130 and be secured thereon. In all other respects, the resilient snap connector system 100 functions similarly to the resilient snap connector system 10.

FIG. 5B depicts the resilient snap connector system 100 employed as a replacement for the typical snap-fit fasteners mounted to the tarp T and hull H. As shown, the resilient snap connector system 100 is provided with a first connector 120a and a second connector 130a. In this instance, the first connector 120a and the second connector 130a are both configured similar to the previously described second connector 130. The first connector 120a replaces the usual female snap-fit fastener component on the tarp T and is fixed thereto by any conventional means, such as fasteners or rivets, with the post thereof extending from underneath the tarp T. The first connector 120a may be capped at the open end of the post by a cap 125. Similarly, the second connector 130a is fixed to the hull H in an upside down orientation so that the open end of the post is oriented towards the hull H. The head and post of each first connector 120a and second connector 130a define respective annular grooves for selective connection to the resilient connector strap 140. This configuration of the resilient snap connector system 100 functions the same in all other respects to the retrofit configuration. It is to be understood that the construction of the first connector 120a and the second connector 130a may also be the same as the first connector 120 and/or a combination of the first connector 120 and the second connector 130 from the retrofit configuration.

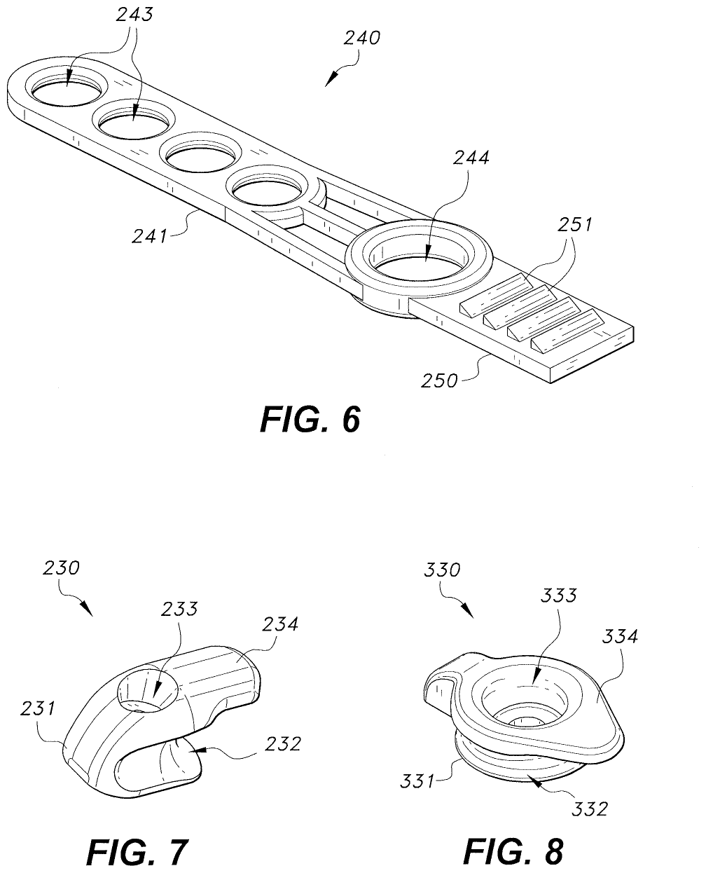

Another embodiment of the resilient connector strap is shown in FIG. 6. In this embodiment, the resilient connector strap 240 enables more adjustable mounting of the resilient connector strap 240 to the first connector 120 and the second connector 130.

As shown, the resilient connector 240 includes a generally oblong connection portion 241 having a plurality of spaced first rings 243 formed thereon. A second ring 244 is spaced from the group of first rings 243. The inner wall of the first rings 243 and the second ring 244 is preferably rounded. The first rings 243 permit adjustable mounting of the resilient connector 240 to the first connector 120, depending on the degree of shrinkage of the tarp T, and the requisite length needed to bridge the connection to the second connector 130. For example, if the shrinkage is minimal, then the first ring 243 nearest the second ring 244 may be safely used, due to the minimal separation between the objects. On the other hand, if the shrinkage is drastic, the first ring 243 furthest from the second ring 244 may be necessary due to the relatively large separation between the objects.

It can be seen that the connection portion 241 is slightly tapered, mainly due to differences between the diameters of the first rings 243 and the second ring 244. It should be understood, however, that the resilient snap connector system 10, 100 is not limited to connectors with the same diameters or dimensions, but rather depends on the application thereof.

The pull tab 250 is preferably an elongate, generally rectangular strip of material extending from one end of the connection portion 241. The pull tab 250 may be provided with one or more ridges 251 to enhance grip during the pulling process. Any other grip enhancing features, such as roughened textures, bumps, and the like, can be used for a similar purpose. In all other respects, the resilient connector strap 240 functions similar to the resilient connector straps 40, 140.

Alternative embodiments of a second connector are shown in FIGS. 7 and 8. In both embodiments, the second connector includes features to enable a more secure capture of the resilient connector strap 40, 140, 240 thereon.

As shown in FIG. 7, the second connector 230 may have a generally U-shaped body having an elongate base 231 and a substantially U-shaped groove 232 formed around the base 231. A hook tab 234 extends generally parallel with the groove 232 from the top of the base 231. The hook tab 234 preferably extends past the length of the base 231. A recessed mounting hole 233 is formed through the body of the second connector 230 to enable mounting of the second connector 230 onto an object, such as the hull H, with fasteners, such as a screw fastener and the like. The hook tab 234 forms a hook to facilitate secure capture and engagement of the corresponding loop in the resilient connector strap 40, 140, 240 during use.

As shown in FIG. 8, the second connector 330 may have a generally tear-shaped body having an elongate base 331 and a broken annular groove 332 formed around the base 331. A tapering hook tab 334 extends from the top of the base 331. The hook tab 334 preferably extends past the length of the base 331. A recessed mounting hole 333 is formed through the body of the second connector 330 to enable mounting of the second connector 330 onto an object, such as the hull H, with fasteners, such as a screw fastener and the like. As with the second connector 230, the hook tab 334 forms a hook to enhance secure capture and engagement of the corresponding ring in the resilient connector strap 40, 140, 240 during use.

Thus, it can be seen that all the embodiments of the resilient snap connector system 10, 100 provide easy, bridged connection between separated parts or objects that requires less physical effort compared to conventional means. Moreover, the resilient snap connector system 10, 100 is a relatively economical solution that may extend the life of the objects to be connected by reducing some of the additional shear stresses induced by tension from stretched fabric and the like.

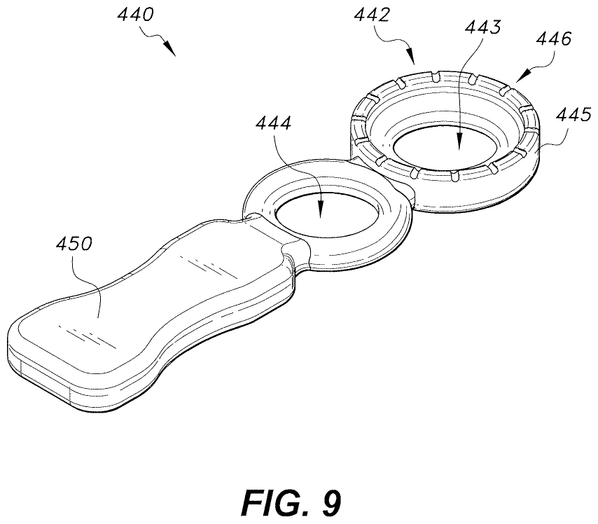

As shown in FIG. 9, another embodiment of the flexible connector 440 is disclosed, which embodiment is similar to FIGS. 3-5B. As disclosed in the other embodiments, a textile anchor point is provided by connecting (e.g. riveting) two fasteners together with the textile in between. The fastener on the bottom surface of the textile serves as a button-like post about which to secure the front loop 443 of the flexible connector 440. A solid surface anchor point is also provided by a similar design. That is, a post-like device is affixed to the solid object about which to secure the rear loop 444 of the flexible connector 440. As seen in the other embodiments, an elongated hand grip 450 extends from the rear loop.

The embodiment disclosed in FIG. 9 differs from the other embodiments by having the front loop 445 having a connecting aperture 443 therein. The front loop 445 is formed with an integrally molded extension thereon 442. The depicted extension or rim is exemplified by a multiplicity of protrusions created by slots 446 forming a “castellated-type” of extension. The extension serves as protection between the textile anchor and the solid surface. That is, the extension envelops the edge of the textile anchor and extends the textile anchor thereby preventing contact between the textile anchor and the solid object. A further benefit would be to allow any water to escape from the textile. Although depicted as “castellated-type” of protrusions, it is readily apparent that other protrusions can exist; namely, a continuous rim, a plurality of protrusions formed as either raised ridges or bumps, three or four equally spaced apart circumferential protrusions, or the like.

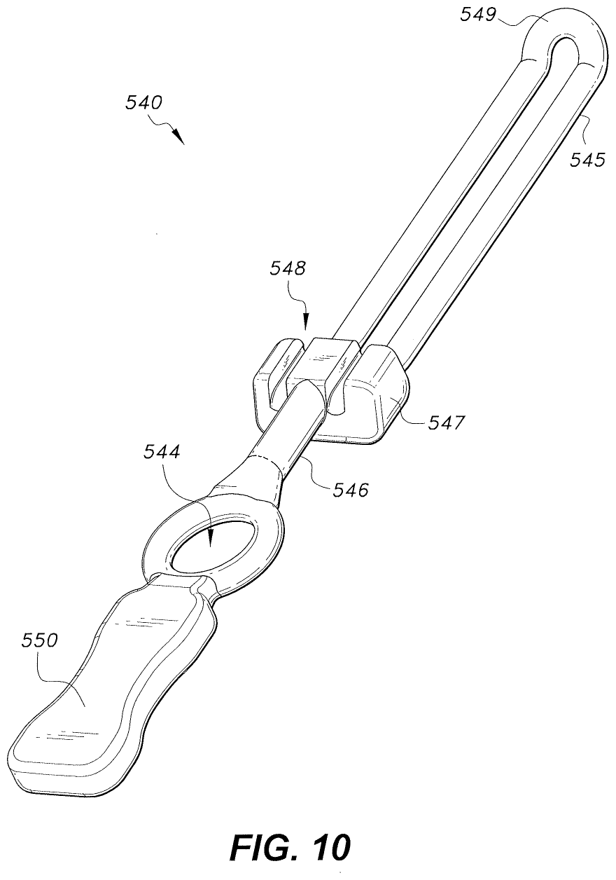

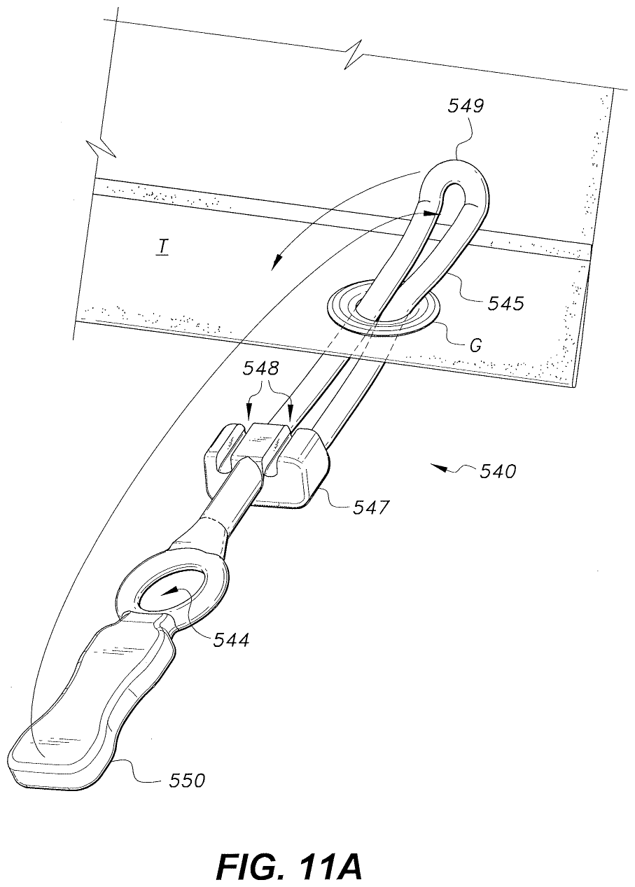

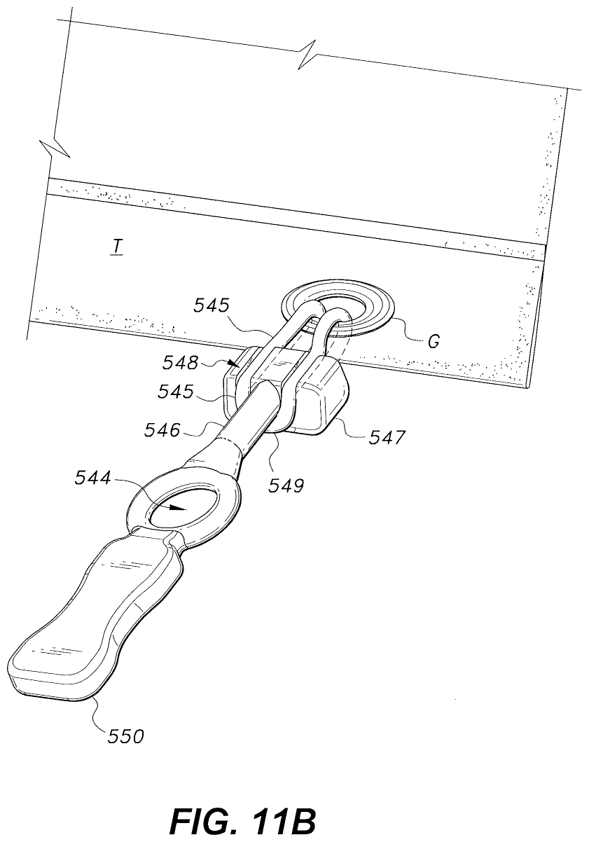

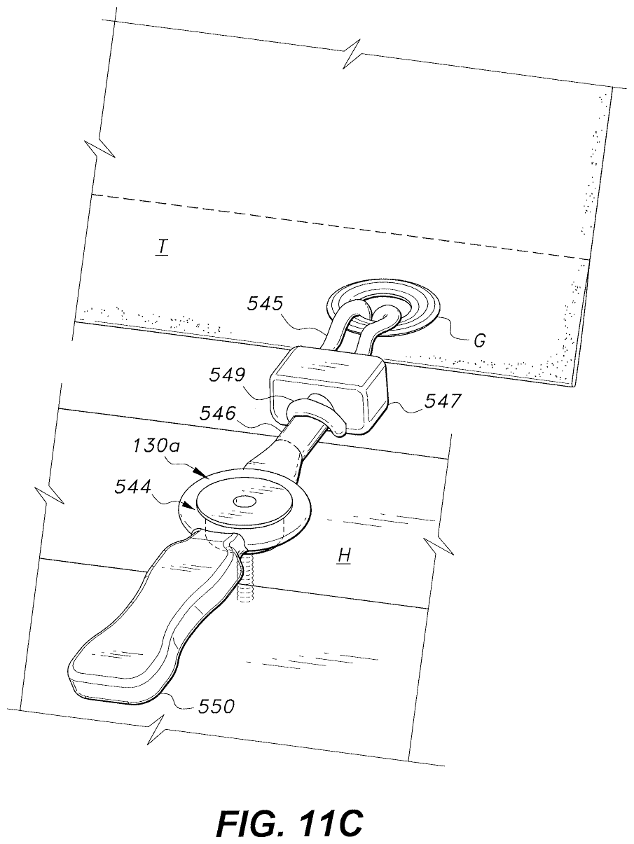

As shown in FIGS. 10 and 11A-11C, another embodiment of the flexible connector 540 is disclosed. In the first embodiment (shown in FIGS. 1 through 2B), the resilient snap connector system 10 was used in conjunction with existing snap-fit fastener hardware. As best seen in FIGS. 1, 2A, and 2B, the resilient snap connector system 10 included a first connector 20 configured to be fixed to an element or component to be positioned for subsequent connection, a second connector 30 configured to be fixed to a stationary object or anchor point, an elongate resilient connector strap 40 with one end coupled to the first connector 20 and the other end coupled to the second connector 30, and an elongate pull tab 50 coupled to the other end of the resilient connector strap 40. The embodiment disclosed in FIGS. 10 and 11A-11C is similar in use but is used when the textile or tarp T is equipped with a grommet G as opposed to a connector 20. This embodiment discloses a flexible connector 540 having integrally formed: i) elongated front loop 545; ii) rear loop 544; iii) connecting piece comprising extension element 546 and stop block 547; and iv) elongated hand grip 550 extending from the rear loop 544. It is noted that the rear loop is depicted as being circular but may be configured as depicted in FIGS. 3-5B. It is further noted that the length of the elongated loop is based on the environment of the use. As depicted in FIG. 10, the length of the elongated loop 545 is equal to the length of the remainder of the flexible connector 540.

In usage, as depicted in FIGS. 11A-11C, a grommet G hole is formed in the tarp T leaving a hem at the end of the tarp. As depicted in FIG. 11A the front loop 545 of the flexible connector is first inserted through the grommet hole G in the textile. As depicted in FIGS. 11A and 11B the grip end 550 is passed through the elongated loop portion extending beyond the textile thereby forming a “hitch-type” knot connection. When tension is applied to the grip end, the “hitch-type” knot tightens as it slides toward the grommet, as seen in FIG. 11B. This tightening may cause the hem (the textile located within the hitch knot) to pinch. The pinched textile will trap moisture and dirt thereby damaging the textile and cause premature wear of the textile. To prevent this from occurring, the stop block 547 limits the “hitch-type” knot tightening as it slides toward the hem and grommet. The stop block 547 also includes a pair of slots 548 that provide an engagement or nesting area for the end of the front loop to be secured, as seen in FIG. 11B. The secured front loop also prevents the hitch knot from loosening when tension is removed. The terminal end of the front loop may be designed with a bent end 549 to aide the securement of the loop to the stop block as seen in FIG. 11B. As seen in FIG. 11C and the other embodiments, the fixed surface is equipped with a post-like anchor 130a, wherein the rear loop 544 is tensioned thereon thus connecting the textile to the solid surface (e.g. hull H).

It is to be understood that the present resilient snap connector system encompasses a variety of alternatives. For example, all the components may be constructed from a variety of materials, such as steel, plastics, composites, and combinations thereof. Depending on the environment, these materials should be resistant to the use environment for extended life and durability. The components may also be colored or color-coded. Moreover, the resilient snap connector system may be provided as kit that includes the resilient connector strap and components that can either be used in conjunction with existing snap-fit fasteners or retrofit with first and second connectors, as described above. Although the above description has been described specifically with tarps T and hulls H for marine vehicles, the resilient snap connector system may be used in any application where separation between connectors exists.

It is to be understood that the present invention is not limited to the embodiments described above, but encompasses any and all embodiments within the scope of the following claims.

We claim:

1. A connector strap, comprising:
an elongate one piece connector strap having a connection portion and a pull tab, the connection portion defining a first end adapted to be selectively attachable to a first connector and a second end adapted to be selectively attachable to a second connector, the connection portion being in a common plane and consists of a first ring opening defined at the first end and constituting the first terminal end of the connection portion and a spaced apart second ring opening defined at the second end and constituting the second terminal end of the connection portion, each of the first and second ring openings being fully enclosed and contiguously located, and the elongate pull tab extending freely from the second terminal end, wherein the first ring opening includes a rim extending above the common plane.

2. The resilient snap connector system as recited in claim 1, wherein the rim is continuous.

3. The resilient snap connector system as recited in claim 1, wherein the rim is segmented into a plurality of protrusions.

4. The resilient snap connector system as recited in claim 3, wherein the plurality of protrusions are three equally spaced apart segments.

5. The resilient snap connector system as recited in claim 3, wherein the plurality of protrusions are four equally spaced apart segments.

6. The resilient snap connector system as recited in claim 3, wherein the plurality of protrusions are a multiplicity of segments having slots therebetween forming a castellated design.

7. A snap connector kit, the kit comprising:
a first connector adapted to be fixed to a first object;
a second connector adapted to be fixed to a second object spaced apart from the first object; and
an elongate one piece connector strap having a connection portion and a pull tab, the connection portion defining a first end adapted to be selectively attachable to the first connector and a second end adapted to be selectively attachable to the second connector, the connection portion being in a common plane and consists of a first ring opening defined at the first end and constituting the first terminal end of the connection portion and a spaced apart second ring opening defined at the second end and constituting the second terminal end of the connection portion, each of the first and second ring openings being fully enclosed and contiguously located, and the elongate pull tab extending freely from the second terminal end, wherein the first ring opening includes a rim extending above the common plane.

8. A connector strap, comprising:
an elongate one piece connector strap having a connection portion and a pull tab, the connection portion defining a first end adapted to be selectively attachable to a first connector and a second end adapted to be selectively attachable to a second connector, the connection portion being in a common plane and consists of a first elongated ring opening defined at the first end and constituting the distal terminal end of the connection portion and a spaced apart second ring opening defined at the second end and constituting the second terminal end of the connection portion, each of the first and second ring openings being fully enclosed, an elongated pull tab extending freely from the second terminal end, and a extension element located between the first and second ring openings, the extension element including a stop block located contiguous to the first ring opening and forming the proximal end of the ring opening, the stop block including a pair of slots disposed thereon to engage the first connector.

9. The connector strap as recited in claim 8, wherein the second ring opening is circular.
